(19) United States
(12) Patent Application Publication
(10) Pub. No.: US 2024/0119197 A1
(43) Pub. Date: Apr. 11, 2024

(54) SYSTEM AND METHOD FOR MAINTAINING STATE INFORMATION WHEN RENDERING DESIGN INTERFACES IN A SIMULATION ENVIRONMENT

(71) Applicant: Figma, Inc., San Francisco, CA (US)

(72) Inventors: Benjamin Drebing, San Francisco, CA (US); Luca Damasco, San Francisco, CA (US); Nikolas Klein, San Francisco, CA (US)

(21) Appl. No.: 18/378,248

(22) Filed: Oct. 10, 2023

Related U.S. Application Data
(60) Provisional application No. 63/414,900, filed on Oct. 10, 2022.

(51) Int. Cl. G06F 30/20; G06F 30/12

(52) U.S. Cl. CPC G06F 30/20; G06F 30/12

(57) ABSTRACT

A computing system implements a simulation environment graphic design system. The graphic design system can be used to create a plurality of cards that individually contain design elements. The computing system can generate production-environment renderings of the individual cards as simulations. In generating the production-environment renderings of the simulation, the computing system processes each card of the sequence to determine a semantic structure for the sequence of cards, where the semantic structure includes nodes that represent a production element of the simulated design. The computing device can further determine, based on the determined semantic structure, whether a design element of each of a first and a second card in the sequence represent a same production element of the simulated design.

### RELATED APPLICATIONS

This application claims benefit of priority to Provisional U.S. Patent Application No. 63/414,900, filed Oct. 10, 2023; the aforementioned priority application being hereby incorporated by reference in its entirety.

### TECHNICAL FIELD

Examples described herein relate to a system and method for rendering design interfaces in a simulation environment.

### BACKGROUND

Software design tools have many forms and applications. In the realm of application user interfaces, for example, software design tools require designers to blend functional aspects of a program with aesthetics and even legal requirements, resulting in a collection of pages which form the user interface of an application. For a given application, designers often have many objectives and requirements that are difficult to track. To facilitate designers, some design tools enable production-environment simulations of cards (or other arrangements of design elements). For example, production-environment simulations can be implemented by rendering a sequence of cards in a manner that reflects state changes that can occur in the production environment. The use of such simulations enable designers to view how a design interface is implemented in a production environment, to enable designers to develop the design interface with the production environment in mind.

### BRIEF DESCRIPTION OF THE DRAWINGS

FIG. 1A illustrates an interactive graphic design system for a computing device of a user, according to one or more examples.

FIG. 1B illustrates a network computing system to implement an interactive graphic design system on a user computing device, according to one or more examples.

FIG. 1C illustrates a network computing system to implement an interactive graphic design system for multiple users in a collaborative network platform, according to one or more examples.

FIG. 2 illustrates a simulation engine, in accordance with one or more embodiments.

FIG. 3 illustrates an example method for implementing a simulation environment for a graphic design system, according to one or more embodiments.

FIG. 4A illustrates a design interface on which a collection of cards is provided, according to one or more embodiments.

FIG. 4B through FIG. 4D illustrate a sequence of renderings, generated in the simulation environment, for a collection of cards, according to one or more embodiments.

FIG. 4E illustrates a semantic memory structure that is determined and used, in connection with cards of the collection being rendered in a simulation environment, according to one or more embodiments.

FIG. 5 illustrates a network computer system on which one or more embodiments can be implemented.

FIG. 6 illustrates a user computing device for use with one or more examples, as described.

### DETAILED DESCRIPTION

According to embodiments, a computer system generates production-environment renderings for graphic design interfaces. In generating the production-environment renderings, the computing system processes individual cards, each of which containing sets of design elements for a user interface or presentation that is to be simulated. The computing system processes the individual cards to determine a semantic structure for the sequence of cards, where the semantic structure includes nodes that represent a production element of the simulated design. The computing device can further determine, based on the determined semantic structure, whether a design element of each of a first and a second card in the sequence represent a same production element of a simulated design.

As described with various examples, the computing system operates to determine when design elements of different cards are semantically the same. Further, the computing system can operate to identify stateful design elements, representing production-environment elements that are subject to state changes (e.g., based on user interaction). When multiple cards are rendered in sequence in a simulated environment, the computing system can determine an update to a state of a stateful design element after an initial render. Subsequently, (e.g., when a next card in the sequence is rendered), the rendering of the stateful design element can be initiated in a manner that accounts for the change in state to the stateful design element resulting from the prior rendering of the sequence.

In embodiments, a stateful design element can correspond to a video element. When multiple cards containing a video element are rendered in a simulation environment, the computing system can determine, based on semantic analysis, that the video elements are the same in the production environment. When a card containing the video element is initially rendered in the simulation environment, state information for the video element is recorded (e.g., showing duration of playback when initial card is rendered). The computing system uses the state information when rendering the video element in a subsequent card in the simulation environment, such that the start time for the video element follows the end time when the video element stopped being rendered with the prior card in the sequence.

One or more embodiments described herein provide that methods, techniques, and actions performed by a computing device are performed programmatically, or as a computer-implemented method. Programmatically, as used herein, means through the use of code or computer-executable instructions. These instructions can be stored in one or more memory resources of the computing device. A programmatically performed step may or may not be automatic.

One or more embodiments described herein can be implemented using programmatic modules, engines, or components. A programmatic module, engine, or component can include a program, a sub-routine, a portion of a program, or a software component or a hardware component capable of performing one or more stated tasks or functions. As used herein, a module or component can exist on a hardware component independently of other modules or components. Alternatively, a module or component can be a shared element or process of other modules, programs or machines.

Some embodiments described herein can generally require the use of computing devices, including processing and memory resources. For example, one or more embodiments described herein may be implemented, in whole or in part, on computing devices such as servers, desktop computers, cellular or smartphones, tablets, wearable electronic devices, laptop computers, printers, digital picture frames, network equipment (e.g., routers) and tablet devices. Memory, processing, and network resources may all be used in connection with the establishment, use, or performance of any embodiment described herein (including with the performance of any method or with the implementation of any system).

Furthermore, one or more embodiments described herein may be implemented through the use of instructions that are executable by one or more processors. These instructions may be carried on a computer-readable medium. Machines shown or described with figures below provide examples of processing resources and computer-readable mediums on which instructions for implementing embodiments of the invention can be carried and/or executed. In particular, the numerous machines shown with embodiments of the invention include processor(s) and various forms of memory for holding data and instructions. Examples of computer-readable mediums include permanent memory storage devices, such as hard drives on personal computers or servers. Other examples of computer storage mediums include portable storage units, such as CD or DVD units, flash memory (such as carried on smartphones, multifunctional devices or tablets), and magnetic memory. Computers, terminals, network enabled devices (e.g., mobile devices, such as cell phones) are all examples of machines and devices that utilize processors, memory, and instructions stored on computer-readable mediums. Additionally, embodiments may be implemented in the form of computer-programs, or a computer usable carrier medium capable of carrying such a program.

System Description

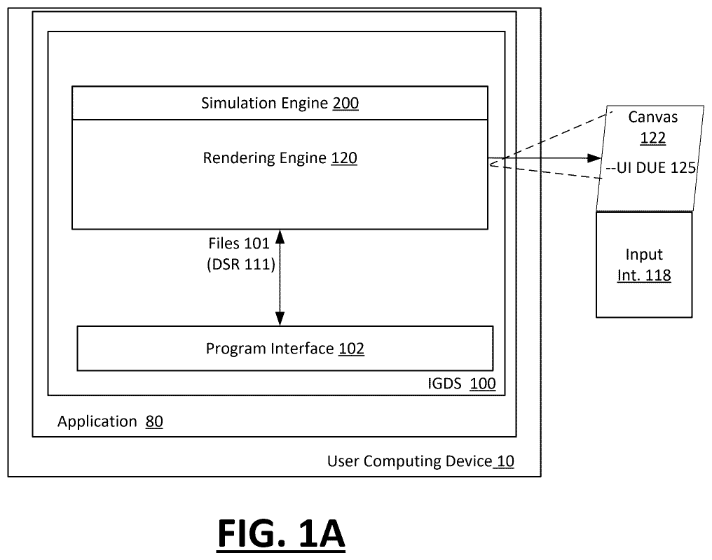

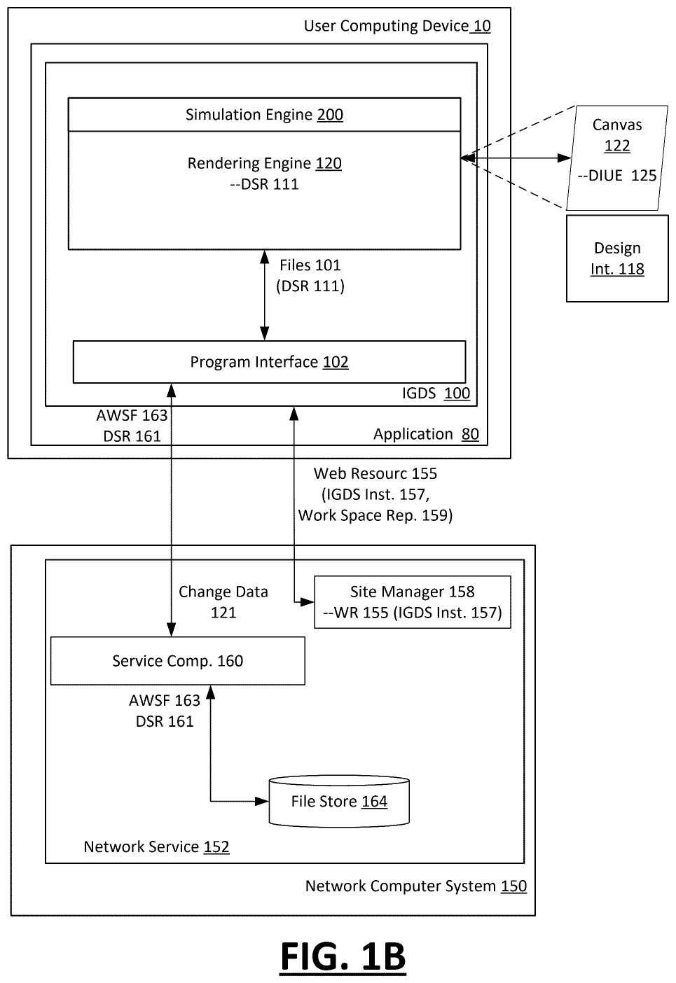

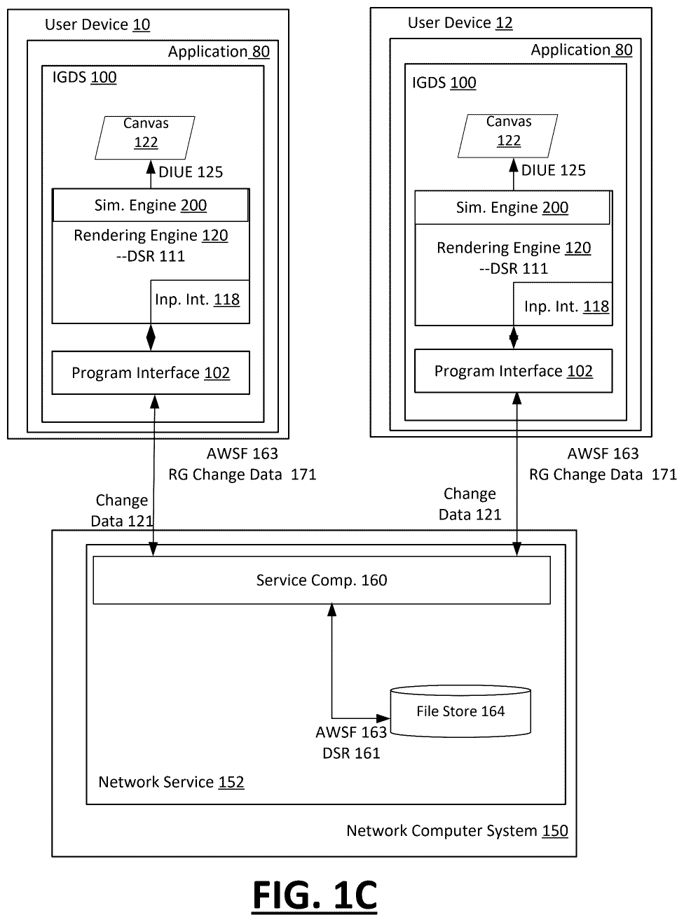

FIG. 1A illustrates an interactive graphic design system for a computing device of a user, according to one or more examples. An interactive graphic design system (“IGDS”) 100 can be implemented in any one of multiple different computing environments. For example, in some variations, the IGDS 100 can be implemented as a client-side application that executes on the user computing device 10 to provide functionality as described with various examples. In other examples, such as described below, the IGDS 100 can be implemented through use of a web-based application 80. As an addition or alternative, the IGDS 100 can be implemented as a distributed system, such that processes described with various examples execute on a network computer (e.g., server) and on the user device 10.

According to examples, the IGDS 100 can be implemented on a user computing device 10 to enable a corresponding user to design various types of interfaces using graphical elements. The IGDS 100 can include processes that execute as or through a web-based application 80 that is installed on the computing device 10. As described by various examples, web-based application 80 can execute scripts, code and/or other logic (the “programmatic components”) to implement functionality of the IGDS 100. Additionally, in some variations, the IGDS 100 can be implemented as part of a network service, where web-based application 80 communicates with one or more remote computers (e.g., server used for a network service) to executes processes of the IGDS 100.

In some examples, web-based application 80 retrieves some or all of the programmatic resources for implementing the IGDS 100 from a network site. As an addition or alternative, web-based application 80 can retrieve some or all of the programmatic resources from a local source (e.g., local memory residing with the computing device 10). The web-based application 80 may also access various types of data sets in providing the IGDS 100. The data sets can correspond to files and libraries, which can be stored remotely (e.g., on a server, in association with an account) or locally.

In examples, the web-based application 80 can correspond to a commercially available browser, such as GOOGLE CHROME (developed by GOOGLE, INC.), SAFARI (developed by APPLE, INC.), and INTERNET EXPLORER (developed by the MICROSOFT CORPORATION). In such examples, the processes of the IGDS 100 can be implemented as scripts and/or other embedded code which web-based application 80 downloads from a network site. For example, the web-based application 80 can execute code that is embedded within a webpage to implement processes of the IGDS 100. The web-based application 80 can also execute the scripts to retrieve other scripts and programmatic resources (e.g., libraries) from the network site and/or other local or remote locations. By way of example, the web-based application 80 may execute JAVASCRIPT embedded in an HTML resource (e.g., web-page structured in accordance with HTML 5.0 or other versions, as provided under standards published by W3C or WHATWG consortiums). In some examples, the rendering engine 120 and/or other components may utilize graphics processing unit (GPU) accelerated logic, such as provided through WebGL (Web Graphics Library) programs which execute Graphics Library Shader Language (GLSL) programs that execute on GPUs.

According to examples, user of computing device 10 operates web-based application 80 to access a network site, where programmatic resources are retrieved and executed to implement the IGDS 100. In this way, the user may initiate a session to implement the IGDS 100 for purpose of creating and/or editing a design interface. In examples, the IGDS 100 includes a program interface 102, an input interface 118, and a rendering engine 120. The program interface 102 can include one or more processes which execute to access and retrieve programmatic resources from local and/or remote sources.

In an implementation, the program interface 102 can generate, for example, a canvas 122, using programmatic resources which are associated with web-based application 80 (e.g., HTML 5.0 canvas). As an addition or variation, the program interface 102 can trigger or otherwise cause the canvas 122 to be generated using programmatic resources and data sets (e.g., canvas parameters) which are retrieved from local (e.g., memory) or remote sources (e.g., from network service).

The program interface 102 may also retrieve programmatic resources that include an application framework for use with canvas 122. The application framework can include data sets which define or configure, for example, a set of interactive graphic tools that integrate with the canvas 122 and which comprise the input interface 118, to enable the user to provide input for creating and/or editing a design interface.

According to some examples, the input interface 118 can be implemented as a functional layer that is integrated with the canvas 122 to detect and interpret user input. The input interface 118 can, for example, use a reference of the canvas 122 to identify a screen location of a user input (e.g., ‘click’). Additionally, the input interface 118 can interpret an input action of the user based on the location of the detected input (e.g., whether the position of the input indicates selection of a tool, an object rendered on the canvas, or region of the canvas), the frequency of the detected input in a given time period (e.g., double-click), and/or the start and end position of an input or series of inputs (e.g., start and end position of a click and drag), as well as various other input types which the user can specify (e.g., right-click, screen-tap, etc.) through one or more input devices. In this manner, the input interface 118 can interpret, for example, a series of inputs as a design tool selection (e.g., shape selection based on location of input), as well as inputs to define attributes (e.g., dimensions) of a selected shape.

Additionally, the program interface 102 can be used to retrieve, from local or remote sources, programmatic resources and data sets which include files 101 which comprise an active workspace for the user. In examples, the files 101 can include a collection of cards, where the cards of the collection provide the design elements for a user interface or presentation when rendered in a production-environment. In examples, the individual cards can represent, for example, an application screen or a state of an application. The retrieved data sets can include one or more cards that include design elements which collectively form a design interface, or a design interface that is in progress. Each file 101 can include one or multiple data structure representations 111 which collectively define the design interface. The files 101 may also include additional data sets which are associated with the active workspace. For example, as described with some examples, the workspace file can store animation data sets which define animation behavior as between objects or states in renderings of the canvas 122.

In examples, the rendering engine 120 uses the data structure representations 111 to render a corresponding design under edit (DUE 125)DUE on the canvas 122, wherein the DUE 125 reflects graphic elements and their respective attributes as provided with the individual pages of the files 101. The user can edit the DUE 125 using the input interface 118. Alternatively, the rendering engine 120 can generate a blank page for the canvas 122, and the user can use the input interface 118 to generate the DUE 125. As rendered, the DUE 125 can include graphic elements such as a background and/or a set of objects (e.g., shapes, text, images, programmatic elements), as well as attributes of the individual graphic elements. Each attribute of a graphic element can include an attribute type and an attribute value. For an object, the types of attributes include, shape, dimension (or size), layer, type, color, line thickness, text size, text color, font, and/or other visual characteristics. Depending on implementation, the attributes reflect properties of two- or three-dimensional designs. In this way, attribute values of individual objects can define, for example, visual characteristics of size, color, positioning, layering, and content, for elements that are rendered as part of the DUE 125.

Network Computing System to Implement IGDS

FIG. 1B illustrates a network computing system to implement an interactive graphic design system on a user computing device, according to one or more examples. A network computing system such as described with an example of FIG. 1B can be implemented using one or more servers which communicate with user computing devices over one or more networks.

In an example of FIG. 1B, the network computing system 150 perform operations to enable the IGDS 100 to be implemented on the user computing device 10. In variations, the network computing system 150 provides a network service 152 to support the use of the IGDS 100 by user computing devices that utilize browsers or other web-based applications. The network computing system 150 can include a site manager 158 to manage a website where a set of web-resources 155 (e.g., web page) are made available for site visitors. The web-resources 155 can include instructions, such as scripts or other logic (“IGDS instructions 157”), which are executable by browsers or web components of user computing devices.

In some variations, once the computing device 10 accesses and downloads the web-resources 155, web-based application 80 executes the IGDS instructions 157 to implement functionality such as described with some examples of FIG. 1A. For example, the IGDS instructions 157 can be executed by web-based application 80 to initiate the program interface 102 on the user computing device 10. The initiation of the program interface 102 may coincide with the establishment of, for example, a web-socket connection between the program interface 102 and a service component 160 of the network computing system 150.

In some examples, the web-resources 155 includes logic which web-based application 80 executes to initiate one or more processes of the program interface 102, causing the IGDS 100 to retrieve additional programmatic resources and data sets for implementing functionality as described by examples. The web resources 155 can, for example, embed logic (e.g., JAVASCRIPT code), including GPU accelerated logic, in an HTLM page for download by computing devices of users. The program interface 102 can be triggered to retrieve additional programmatic resources and data sets from, for example, the network service 152, and/or from local resources of the computing device 10, in order to implement the IGDS 100. For example, some of the components of the IGDS 100 can be implemented through web-pages that can be downloaded onto the computing device 10 after authentication is performed, and/or once the user performs additional actions (e.g., download one or more pages of the workspace associated with the account identifier). Accordingly, in examples as described, the network computing system 150 can communicate the IGDS instructions 157 to the computing device 10 through a combination of network communications, including through downloading activity of web-based application 80, where the IGDS instructions 157 are received and executed by web-based application 80.

The computing device 10 can use web-based application 80 to access a website of the network service 152 to download the webpage or web resource. Upon accessing the website, web-based application 80 can automatically (e.g., through saved credentials) or through manual input, communicate an account identifier to the service component 160. In some examples, web-based application 80 can also communicate one or more additional identifiers that correlate to a user identifier.

Additionally, in some examples, the service component 160 can use the user or account identifier of the user identifier to retrieve profile information from a user profile store. As an addition or variation, profile information for the user can be determined and stored locally on the user's computing device 10.

The service component 160 can also retrieve the files of an active workspace (“active workspace files 163”) that are linked to the user account or identifier from a file store 164. The profile store can also identify the workspace that is identified with the account and/or user, and the file store 164 can store the data sets that comprise the workspace. The data sets stored with the file store 164 can include, for example, the pages of a workspace, data sets that identify constraints for an active set of workspace files, and one or more data structure representations 161 for the design under edit which is renderable from the respective active workspace files.

Additionally, in examples, the service component 160 provides a representation 159 of the workspace associated with the user to the web-based application 80, where the representation identifies, for examples, individual files associated with the user and/or user account. The workspace representation 159 can also identify a set of files, where each file includes one or multiple pages, and each page including objects that are part of a design interface.

On the user device 10, the user can view the workspace representation through web-based application 80, and the user can elect to open a file of the workspace through web-based application 80. In examples, upon the user electing to open one of the active workspace files 163, web-based application 80 initiates the canvas 122. For example, the IGDS 100 can initiate an HTML 5.0 canvas as a component of web-based application 80, and the rendering engine 120 can access one or more data structures representations 111 of a design interface under edit, to render the corresponding DUE 125 on the canvas 122.

The service component 160 may also determine, based on the user credentials, a permission setting or role of the user in connection with the account identifier. The permission settings or role of the user can determine, for example, the files which can be accessed by the user. In some examples, the implementation of the rendering engine 120 on the computing device 10 can be configured based at least in part on the role or setting of the user. For example, the user's ability to specify constraints for the DUE 125 can be determined by the user's permission settings, where the user can be enabled or precluded from creating constraints 145 for the DUE 125 based on their respective permission settings. Still further, in some variations, the response action which the user can take to resolve a conflict can be limited by the permission setting of the user. For example, the ability of the user to ignore constraints 145 can be based on the permission setting of the user.

In examples, the changes implemented by the rendering engine 120 to the DUE 125 can also be recorded with the respective data structure representations 111, as stored on the computing device 10. The program interface 102 can repeatedly, or continuously stream change data 121 to the service component 160, wherein the updates reflect edits as they are made to the DUE 125 and to the data structure representation 111 to reflect changes made by the user to the DUE 125 and to the local data structure representations 111 of the DUE 125. The service component 160 can receive the change data 121, which in turn can be used to implement changes to the network-side data structure representations 161. In this way, the network-side data structure representations 161 for the active workspace files 163 can mirror (or be synchronized with) the local data structure representations 111 on the user computing device 10. When the rendering engine 120 implements changes to the DUE 125 on the user device 10, the changes can be recorded or otherwise implemented with the local data structure representations 111, and the program interface 102 can stream the changes as change data 121 to the service component 160 in order to synchronize the local and network-side representations 111, 161 of the DUE 125. This process can be performed repeatedly or continuously, so that the local and network-side representations 111, 161 of the DUE 125 remain synchronized.

Collaborative Network Platform

FIG. 1C illustrates a network computing system to implement an interactive graphic design system for multiple users in a collaborative network platform, according to one or more examples. In an example of FIG. 1C, a collaborative network platform is implemented by the network computing system 150, which communicates with multiple user computing devices 10, 12 over one or more networks (e.g., World Wide Web) to implement the IGDS 100 on each computing device. While FIG. 1C illustrates an example in which two users utilize the collaborative network platform, examples as described allow for the network computing system 150 to enable collaboration on design interfaces amongst a larger group of users.

With respect to FIG. 1C, the user computing devices 10, 12 can be assumed as being operated by users that are associated with a common account, with each user computing device 10, 12 implementing a corresponding IGDS 100 to access the same workspace during respective sessions that overlap with one another. Accordingly, each of the user computing devices 10, 12 may access the same set of active workspace files 163 at the same time, with the respective program interface 102 of the IGDS 100 on each user computing device 10, 12 operating to establish a corresponding communication channel (e.g., web socket connection) with the service component 160.

In examples, the service component 160 can communicate a copy of the active workspace files 163 to each user computing device 10, 12, such that the computing devices 10, 12 render the DUE 125 of the active workspace files 163 at the same time. Additionally, each of the computing devices 10, 12 can maintain a local data structure representation 111 of the respective DUE 125, as determined from the active workspace files 163. The service component 160 can also maintain a network-side data structure representation 161 obtained from the files of the active workspace 163, and coinciding with the local data structure representations 111 on each of the computing devices 10, 12.

The network computing system 150 can continuously synchronize the active workspace files 163 on each of the user computing devices. In particular, changes made by users to the DUE 125 on one computing device 10, 12 may be immediately reflected on the DUE 125 rendered on the other user computing device 10, 12. By way of example, the user of computing devices 10 can make a change to the respective DUE 125, and the respective rendering engine 120 can implement an update that is reflected in the local copy of the data structure representation 111. From the computing device 10, the program interface 102 of the IGDS 100 can stream change data 121, reflecting the change of the user input, to the service component 160. The service component 160 processes the change data 121 of the user computing device. The service component 160 can use the change data 121 to make a corresponding change to the network-side data structure representation 161. The service component 160 can also stream remotely-generated change data 171 (which in the example provided, corresponds or reflects change data 121 received from the user device 10) to the computing device 12, to cause the corresponding IGDS 100 to update the DUE 125 as rendered on that device. The computing device 12 may also use the remotely generated change data 171 to update with the local data structure representation 111 of that computing device 12. The program interface 102 of the computing device 12 can receive the update from the network computing system 150, and the rendering engine 120 can update the DUE 125 and the respective local copy of 111 of the computing device 12.

The reverse process can also be implemented to update the data structure representations 161 of the network computing system 150 using change data 121 communicated from the second computing device 12 (e.g., corresponding to the user of the second computing device updating the DUE 125 as rendered on the second computing device 12). In turn, the network computing system 150 can stream remotely generated change data 171 (which in the example provided, corresponds or reflects change data 121 received from the user device 12) to update the local data structure representation 111 of the DUE 125 on the first computing device 10. In this way, the DUE 125 of the first computing device 10 can be updated as a response to the user of the second computing device 12 providing user input to change the DUE 125.

To facilitate the synchronization of the data structure representations 111, 111 on the computing devices 10, 12, the network computing system 150 may implement a stream connector to merge the data streams which are exchanged between the first computing device 10 and the network computing system 150, and between the second computing device 12 and the network computing system 150. In some implementations, the stream connector can be implemented to enable each computing device 10, 12 to make changes to the network-side data representation 161, without added data replication that may otherwise be required to process the streams from each device separately.

Additionally, over time, one or both of the computing devices 10, 12 may become out-of-sync with the server-side data representation 161. In such cases, the respective computing device 10, 12 can redownload the active workspace files 163, to restart the maintenance of the data structure representation of the DUE 125 that is rendered and edited on that device.

Simulation Engine

With reference to FIG. 1A through FIG. 1C, in examples, the IGDS 100 can implement a simulation engine 200 for users. In some examples, the simulation engine 200 can implement alternative modes, including a design mode and a simulation mode. In the simulation mode, the simulation engine 200 generates simulation renderings for individual cards of a collection. The simulation engine 200 can render a sequence of cards in order to provide users with a production-environment simulation of a design interface that is in progress or under edit. In examples, the simulation engine 200 can be implemented as part of the rendering engine 120. In variations, the simulation engine 200 can be implemented through another component.

As described with examples, the simulation engine 200 can implement processes to efficiently generate a simulation rendering, where stateful design elements are interactive and/or dynamic, so that the stateful design elements change states responsive to user input or other events when the simulation renderings are generated. Among other benefits, examples enable such simulation renderings to render stateful design elements in a manner that is interactive and/or dynamic, to accurately replicate a production-environment for the simulated design. When stateful design elements are rendered with a simulated rendering of a card, the state of the design element may change (e.g., responsive to user input). For example, the stateful design element can correspond to a video element, which when played back, undergoes state change (e.g., playback time). In examples, the simulation engine 200 renders multiple cards where a state of the rendered stateful element is progressed from card to card, to more accurately simulate how the stateful element would be rendered in a production-environment.

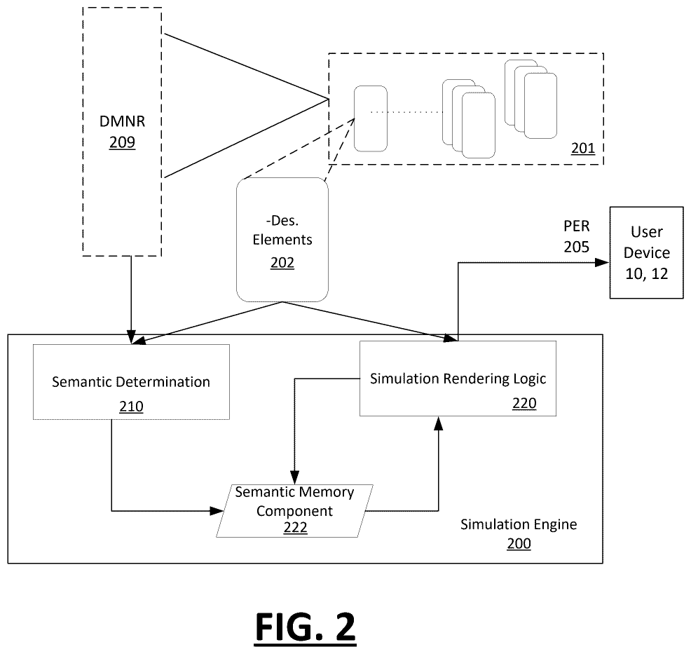

FIG. 2 illustrates an example simulation engine, in accordance with one or more embodiments. The simulation engine 200 can be implemented or otherwise provided with the IGDS 100 in order to enable users to simulate how a sequence of cards would be rendered in the production-environment (“production-environment rendering” or “simulation rendering”), where each card includes a top-level frame that contains a set of design elements. Accordingly, the simulation engine 200 can generate production-environment renderings as an output, often utilizing multiple cards 200 to of a collection 201, where design elements of each card 202 combine to simulate a set of production elements for a user interface or presentation in the production-environment.

In some examples, a simulation engine 200 can be implemented as part of the rendering engine 120 for the IGDS 100. For example, the IGDS 100 can implement alternative modes, including a design mode and a simulation mode, where in the simulation mode, the rendering engine 120 executes processes of simulation engine 200 to render production-environment renderings 205 as an output, where the production-environment renderings 205 simulate a design interface when it is in production. The production-environment renderings 205 can be provided to user devices 10, 12, to enable designs and users of the IGDS 100 to view how designs in progress may appear in the production environment. In variations, the simulation engine 200 can be implemented as a separate component or application.

Logical Hierarchical Representation of Cards

As described with examples, the IGDS 100 enables a user to interact with a canvas to create design elements, where design elements can have spatial and logical relationships one another. Design elements can be linked, for example, as having parent/child relationship, or alternatively referred to as nested design elements. In examples, nested design elements can have a spatial and logical relationship with one another. For example, a design element can be nested within another design element, meaning a boundary or frame of the design element (e.g., child element) is contained within the boundary or frame of the other design element (e.g., parent element). Further, nested design elements can be logically linked, such as in a manner where design input to either design element can trigger rules or other logic that affect the other design element. The rules or logic that affect nested design elements can serve to maintain the design elements in their spatial relationship, such that one node remains the parent of the other (or one node remains the child of the other) despite, for example, resize or reposition input that would otherwise affect the parent-child spatial relationship. Thus, for example, nested design elements can be subject to a common set of constraints, as well as other functional features (e.g., auto-layout). Still further, as another example, the design input to move one of the design elements of a nested pair can result in the other design element being moved or resized.

Further, the IGDS 100 enables users to specify flows that specify sequences (including alternative sequences) amongst multiple cards. For example, a user can specify logical connections amongst a collection 201 of cards 202, where the logical connections specify a sequence. As individual cards 202 may specify, for example, alternative states of same screen or interface, the use of such logical connectors can specify state changes or flows of the user interface or presentation when in production, where the state changes or flows are responsive to events (e.g., user input) which may occur in such production-environment. The IGDS 100 can determine and utilize a common hierarchical logical data structure (“design-mode nodal representation 209”) to represent a collection of cards. For example, a hierarchical nodal representation can be maintained for the collection of cards 201, where the representation includes a top-level node and sub-nodes with additional hierarchically arranged nodes. Accordingly, in examples, each card 202 of the collection can be represented by a root node (Level 0, or top-most level node), and each design element can be represented as a sub-node of the root node. Within each root node, sub-nodes can be arranged to have different levels. A top-most sub-node of the root node (i.e., Level 1 node) can include design elements of the card 202 that are not children of any other design elements except for the top-level frame represented by the root node. In turn, any child design element to one of the design elements represented by a top-level sub-node (Level 1) can be represented by a second level sub-node (i.e., Level 2 node) and so forth. The design-mode nodal representation 209 can be determined for each card 202, and further combined for all of the cards of the collection 201. The design-mode nodal representation 209 of the collection 201 can be provided by the IGDS 100 as, for example, part of a separate panel in a tool panel of the IGDS 100.

Simulation Rendering Logic

In examples, the simulation engine 200 includes processes represented by semantic determination logic 210 and simulation rendering logic 220. The simulation rendering logic 220 generates a production-environment rendering 205 from each card 202 that is processed by the simulation engine 200, where the production-environment rendering 205 includes production elements of a simulated user interface or presentation. Further, the production-environment renderings 205 can be interactive or dynamically responsive to events, such as responsive to user input that simulates an end user input in the production-environment. Upon generating an initial production-environment rendering 205 for a card that is initially selected, the simulation rendering logic 220 generates a next production-rendering from a card 202 that is the next selection from the collection 201, and so forth, such that a sequence of cards 202 is selected and used to generate a respective production-rendering 205 for the collection. The selection of individual cards 202 for the renderings can be based on, for example, user input or interaction with one of the production-environment renderings 205, predefined logical connections amongst the cards 202 and/or other events. In this way, a sequence of cards 202 can be dynamically selected and used to generate production-environment renderings 205. In other implementations, a sequence of cards 202 are preselected for rendering by simulation rendering logic 220.

Semantic Determination Logic

While each card 202 can include a plurality of design elements, design elements provided on different cards 202 of the collection 201 may represent a same production element. For example, multiple cards 202 of the collection 201 can represent the same production-environment element in alternative states. The simulation engine 200 can implement semantic determination logic 210 to process each card 202 that is rendered through execution of the simulation rendering logic 220, in order to determine a semantic structure that is representative of production elements of the simulated output. In some examples, the semantic determination logic 210 maintains and updates a semantic memory component 222, where the memory component's structure corresponds to a semantic structure determined through processing of individual cards 202. The semantic structure includes a nodal representation of the design elements of one or multiple cards 202 rendered by the simulation rendering logic 220, where each node of the semantic structure represents a production element of the simulated user interface or presentation. In examples, the semantic determination logic 210 processes a sequence of cards 202 to build the semantic structure for a given production rendering, where the sequence can be determined by user input, randomly or responsive to some other input.

Beginning with a first card of the sequence, the semantic determination logic 210 scans (i) respective design elements of the first card, and/or (ii) a portion of the design-mode nodal representation 209 of the collection 201 corresponding to the particular card 202, in order to determine a semantic structure of the design elements of the card. The semantic structure identifies a spatial and/or logical relationship amongst individual design elements of the card, such as design elements are nested. As an addition or variation, the semantic structure can identify other types of logical connections amongst design elements that appear on the same card. Still further, the semantic structure can also identify design elements which overlap one another (with or without an associated logical relationship).

In examples, the semantic structure can be in graph form, with each node of the graph representing a design element of the first card 202. In some examples, the semantic determination logic 210 scans the design elements of the first card 202 to determine one or more top-level design elements, corresponding to design elements that have no parent other than the top-level frame of the card itself. For example, a name or identifier of each top-level design element is identified. The name/identifier (or other property or characteristic) of the top-level design elements are used to identify the root node of the card in the design-mode nodal representation 209 for the collection 201. Once the root node is identified, the semantic data structure is determined based on the hierarchical structure of the corresponding portion of the design-mode nodal representation 209. For example, the semantic data structure can be implemented in graph-form, with (i) the left-most graph node representing the root node (i.e., Level 0 of the hierarchical structure, representing the card); (ii) the first level of the graph node representing the top-most sub-nodes of the design-mode nodal representation 209 (Level 1 of the hierarchical structure, corresponding to design elements with no parent other than the frame of the card); (iii) the second level of the graph node representing the first nesting level of design elements of the hierarchical nodal representation 209 (Level 2 of the hierarchical structure); and so on. In examples, each graph node can also be associated with a name, property and/or characteristic of the corresponding design element, and/or node of the hierarchical, logical nodal representation 209. In this way, each node of the graph-node structure coincides with one of the design elements, and the connections of the graph-node structure define nested relationships amongst identified design elements. In examples, the semantic determination logic 210 makes an initial determination of the semantic structure of the first structure, and then generates the semantic memory component 222 accordingly.

For a second and subsequently rendered card 202, the semantic determination logic 210 scans the design elements of the second (or subsequent) card 202 to determine one or more top-level design elements, corresponding to design elements that have no parent other than the top-level frame of the second card. A name or other identifier of each top-level design element of the second card is identified. The name (or other property or characteristic) of the top-level design elements can be used to identify the root node of the second card (and subsequent cards) in the design-mode nodal representation 209. Once the root node of the second card is identified, the semantic data structure of the respective card can be determined, based at least in part on the hierarchical structure of the corresponding portion of the design-mode nodal representation 209. The semantic structure of the second or subsequent card can be compared to the existing semantic structure, as provided by the semantic memory component 222, to determine design elements of the second or subsequent card which are not represented by the existing semantic structure. For each identified design element that is not represented by the existing semantic structure, the semantic determination logic 210 executes to build the identified design element as an additional node of the semantic structure, and the semantic memory component 222 is updated accordingly. This process is repeated for each card of the collection 201 that is rendered by the simulation engine 200, such that semantic structure is updated to include newly identified nodes in its graph form structure. In this way, the semantic memory component 222 can be in the form of graph, where the nodes represent production elements of the simulated design.

In examples, the semantic determination logic 210 can identify stateful design elements which may be present in individual cards 202. A stateful element refers to a design element that can be subjected to a state change in a production (or simulated production) environment. A stateful element can correspond to any design element which can vary by a change to a property when rendered in a simulation. By way of example, a stateful element can correspond to a video element, where the state of the video element can include a playback time. In other variations, the stateful property for a media file can correspond to a playback speed or format, a volume, or any other detectable characteristic of the media output that may change as a result of the user input or other events. For example, in connection with rendering a given card 202, the simulation rendering logic 220 can render a video element for a duration that can vary based on user input. Once the user input is received, playback of the video element is stopped and the next card is rendered. In such case, the playback time of the video element at the moment before the user input is received corresponds can define a state of the video element, just before the next card is rendered. The simulation rendering logic 220 can record the playback time as state information with the semantic memory component 222. Upon the next card being loaded, the simulation rendering logic 220 can use the semantic structure recorded with the semantic memory component 222, to identify the stateful design element (e.g., video element) as being the same as the design element of the prior card. Based on the determination, the simulation rendering logic 220 can use state information recorded with the simulation rendering logic 220 to when rendering, or initiating rendering of the identified stateful design element. In the example of the video element, this results in the video element initiating playback from the recorded playback time.

While some examples as described are specific to video or media, embodiments as described can be applied to other types of stateful design elements. For example, an input selector (e.g., date field selector) can enable a user to select a date from a set of possible choices (e.g., over course of month). In a particular state, the user's selection of a particular option (e.g., specific date) can be highlighted. In examples, the change in the state of an input selector can be simulated through rendering of multiple cards, so as to simulate, for example, a user scrolling through multiple options (e.g., multiple dates on a calendar view).

As another example, a stateful design element can correspond to a checkbox which can vary between a check state and an uncheck state. If the checkbox is reused in a subsequent frame, the state of the checkbox can be retained and displayed in the simulation rendering of a subsequent card. As another example, the design element can render a media field where the viewing angle changes. For example, the media feed can correspond to live gaming content which can be rendered, where a user can view renderings in different angles. Alternatively, the media feed can be generated by a camera that can be pivoted to change the viewing angle. In such examples, the simulation renderings as between cards can identify the feed as a stateful element, where the state can change to alter the perspective or viewing angle of the feed.

Methodology

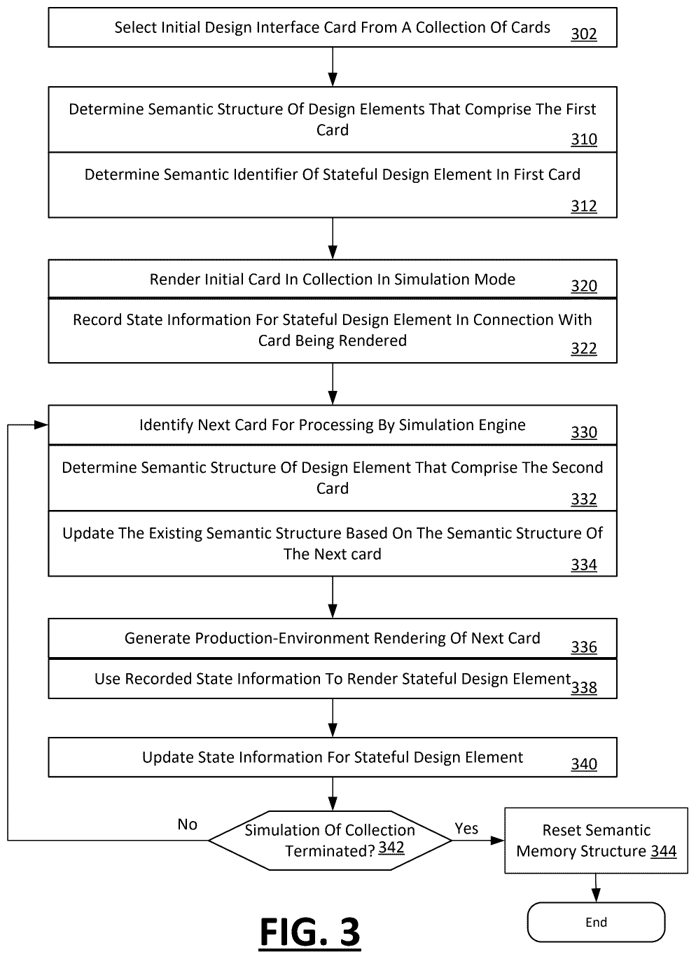

FIG. 3 illustrates an example method for implementing a simulation environment for a graphic design system, according to one or more embodiments. A method such as described with an example of FIG. 3 can be implemented using a simulation engine for a graphic design system, such as described with examples of FIG. 1A through FIG. 1C and FIG. 2. Accordingly, in describing examples of FIG. 3, reference may be made to elements of FIG. 1A through FIG. 1C and FIG. 2 for purpose of illustrating functionality for implementing a step or sub-step being described.

With reference to FIG. 3, in step 302, an initial design interface card is selected from a collection of cards for rendering by the simulation engine 200. Depending on implementation, the selection of the initial card can be based on user-selection, predetermined, or responsive to some other event. As described with various examples, one or more users can utilize the IGDS 100 to generate a collection of cards, where each card includes design elements that depict or otherwise represent a particular operational state of a user interface or presentation in production. For example, the cards of a collection can depict the screens of an application (e.g., mobile app), beginning with a home screen. In such examples, each card can represent (i) a particular application screen (e.g., home screen), or (ii) an application screen in a particular state (e.g., start screen with interactive features to receive user input). Accordingly, in such examples, multiple cards can represent one application screen, and design elements of different cards can represent the same element of the user interface or presentation (“production element”). Further, designers can use connectors to specify flows amongst cards, where the flows specify a sequence amongst a subset of the cards, based on user interaction or other events. The simulation engine 200 can render individual cards to be interactive, based on, for example, the connectors and/or design elements specified with individual cards.

In step 310, the simulation engine 200 processes the selected card, and/or information associated with the initial card 202 or collection 201, to determine a semantic structure for the card. The semantic structure can identify the design elements of the initial card, as well as one or more types of spatial and/or relationships amongst the design elements. In some examples, the semantic structure identifies nested relationships amongst the design elements of the initial card. The semantic structure can be in graph form, with each design element of the initial card being represented by a node of the graph, and nested relationships amongst the design elements represented by connectors of the graph. In this way, the semantic structure can represent a semantic identifier of individual nodes of the semantic structure (representing design elements of the initial card). The semantic identifier of each node can correspond to, for example, the name of the corresponding design element, combined with the nodal path of the node within the semantic structure (e.g., relative to the root node, representing a container of the card). The simulation engine 200 can also associate additional properties with each node, such as attributes that identify a type, color, shading, line thickness or other property of the corresponding design element. The information used to determine the semantic structure can include the hierarchical design-mode representation 209 of the collection 201, where the hierarchical arrangements specify nested relationships amongst the design elements.

In step 312, the simulation engine 200 can also identify one or more design elements of the initial card which represent corresponding stateful design elements. As described with other examples, a stateful design element refers to a design element that can be subjected to a state change in a simulation environment. By way of example, a stateful design element can correspond to a video element that can be played back, where the playback time of the video element can define a state of the video element.

Further, in step 320, the simulation engine 200 can generate a production-environment rendering using the initial card. The generation of the rendering can be performed concurrently, or at the same time as the semantic structure for the initial card being determined. Based on implementation, the production-environment rendering can receive interaction by the user, to simulate actual user interaction in the production-environment. In this way, the state of the stateful design element can change once the initial card is rendered. For example, the stateful design element can correspond to a video element that can be played back when the production-environment rendering of the initial card is initiated. The user can interact with the video element when the production-environment rendering is generated to, for example, initiate, pause, stop or perform some other interaction with the playback.

In step 322, the simulation engine 200 records the state of each of the one or more stateful design elements after the rendering of the initial card is generated. After the rendering is generated, the user can interact with the rendering to change the state of the stateful element. For example, the stateful element can correspond to a video element, and the simulation engine 200 can playback the video in connection with the rendering of the initial card. The state information can be recorded in association with a semantic identifier of the stateful design element. For example, the semantic structure can be in graph form, and the stateful design element can be identified by a nodal path of the stateful element within the graph representation of the semantic structure. The nodal path can identify, for example, a name (or other identifier) of each upstream node to the root node, corresponding to each parent design element of that stateful design element. In this way, the semantic identifier of the stateful element can identify the nodal position or path of the stateful element, as well as the names of the corresponding design elements.

In examples, the simulation engine 200 maintains a semantic memory component 222 that records the determined semantic structure. In particular, the recorded state information can include the semantic identifier of individual design elements, including the stateful design elements. For the stateful design element, the simulation engine 200 can record the determined state information in association with the semantic identifier of the corresponding node of the semantic structure.

In step 330, the simulation engine 200 identifies a next card for the simulation rendering based on, for example, a user input or detected event and/or a predetermined workflow. The predetermined workflow can be specified by, for example, connectors which the user(s) can specify between cards 202 of the collection.

In step 332, the simulation engine 200 processes the next card, and/or information associated with the initial card 202 or collection 201, to determine a semantic structure for the next card. As with the initial card, the semantic structure can identify the design elements of the initial card, as well as one or more types of spatial and/or relationships (e.g., nested relationships) amongst the design elements. The semantic structure can also be based at least in part on the hierarchical design-mode representation 209 of the collection 201. Further, the semantic identifier of individual nodes of the next card can be determined from the semantic structure, such as based on the name of the corresponding design element, the nodal path of the node within the semantic structure, and/or other properties (e.g., a type, color, shading, line thickness or other property of the corresponding design element).

In step 334, the simulation engine 200 can update the existing determined semantic structure, based on the semantic structure determined for the next card. In determining the semantic structure, the simulation engine 200 can determine whether individual design elements of the next card are represented by the existing semantic structure, as determined from the first card or any other prior cards. The existing semantic structure can be recorded with the semantic memory component 222. In examples, the simulation engine 200 compares a semantic identifier of individual design elements of the next card with semantic identifiers of the existing semantic structure (as recorded with the semantic memory component 222). For each design element of the next card, if the corresponding semantic identifier is present in the existing semantic structure, the simulation engine 200 does not update a structure of the semantic memory component 222. If the corresponding semantic identifier is not present in the existing semantic structure, then the simulation engine 200 updates the semantic memory structure to include an additional node representing the identified design element.

In step 336, the simulation engine 200 generates a production-environment rendering of the next card. The generation of the rendering can be performed concurrently or at the same time as the determination of the semantic structure. In generating the rendering, the simulation engine accesses the semantic memory component 222 to determine information, such as the state of individual design elements which are stateful. For stateful design elements, in step 338, the simulation engine 200 identifies state information associated with the corresponding semantic identifier and renders the design element to reflect a state represented by the state information. Thus, for example, if the initial card includes a video element that is played back for a given time interval, then the rendering of the next card initiates the playback of the video element at the end of the given time interval.

Further, in step 340, the simulation engine 200 can update the state information of the stateful design element while the rendering of the next card is ongoing. The update of the state information for that design element can be based on, for example, user input and/or other events which occur after the rendering is generated. Thus, for example, if video element continues to playback for a second time interval, the simulation engine 200 updates the semantic memory component 222, so that the semantic identifier associated with the video element reflects the current playback state of the video element. In step 342, a determination is made as to whether another card of the collection is to be rendered in the simulation. The determination can be based on, for example, logical associations between cards, user interactions with rendered cards during the simulation, and/or the structure, arrangement or number of cards. If the determination is that there is another card to render in the simulation (“No”), then steps 330-340 are repeated for the next card.

In examples, steps 330 through steps 340 can be repeated for each additional card that is rendered through the simulation engine 300 until renderings of the collection 201 in the simulation environment is terminated (step 342). If the determination in step 342 is that no other cards are to be simulated (or termination of the simulation), then the process can end. In some examples, the semantic memory component 222 can be reset for the next simulation, which can occur for the same or different collection.

### Example Design Interface and Simulation

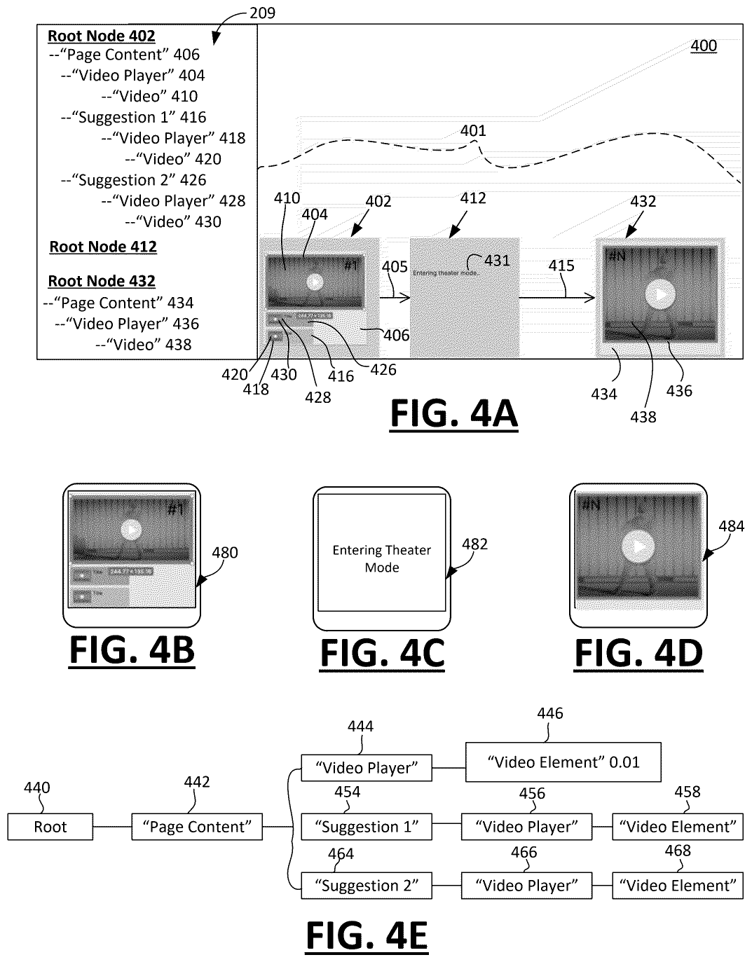

FIG. 4A illustrates a design interface on which a collection of cards is provided, according to one or more embodiments. FIG. 4B through FIG. 4D illustrate a sequence of renderings, generated in the simulation environment, for the collection of cards. FIG. 4E illustrates a semantic memory structure that is determined and used, in connection with cards of the collection being rendered in a simulation environment, according to one or more embodiments. In describing examples of FIG. 4A, FIG. 4B through FIG. 4D and FIG. 4E, reference may be made to elements of FIG. 1A through FIG. 1C and FIG. 2 for the purpose of illustrating functionality for implementing an example being described.

With reference to FIG. 4A, a design interface 400 includes a first card 402, a second card 412 and a third card 432, collectively forming a card collection 401. Connections 405, 415 can in combination specify a sequence in which the individual cards are to be rendered in a production-environment, where the sequence can be determined by events or user input. The IGDS 100 can maintain a design-mode nodal representation 209 for design elements of the collection 401. Each design element can be identified as a node on the design-mode nodal representation 209, with each card 402, 412, 432 having a corresponding root node from which other nodes representing design elements of that card are hierarchically arranged to reflect nested relationships.

In an example shown, the first card 402 includes a first video element 410 that is nested within multiple other design elements. The other design elements include a design element 404 representing a video player, which is also nested within a design element 406 representing page content, both of which are nested within the frame of the first card 402. The first card 402 also includes a second video design element 420 that is nested within another design element 418 representing a second video player, which in turn is nested within another design element 416 representing a suggestion box. The suggestion box design element 416 is shown to be nested within page content design element 406. The first card 402 also includes a third video design element 430 that is that is nested within another design element 428 representing a third video player, which in turn is nested within another design element 426 representing a second suggestion box 426, which in turn is nested within the page content design element 406.

With further reference to FIG. 4A, the second card 412 includes text element 431. The third card 432 includes a video element 438, which is nested within a design element 436 that represents a video player, which in turn is nested within a design element 434 which represents a page content.

FIG. 4B through FIG. 4D illustrate the simulation engine 200 generating renderings of the cards 402, 412 and 432 in sequence. With reference to FIG. 4B, the simulation engine 200 generates a production-environment rendering 480 for the first card 402. In an example shown, the rendering 480 of the first card 402 results in video playback of the video element 410 for a given interval (e.g., 1 second), before, as shown in FIG. 4C, the simulation engine 200 generates a rendering 482 of the next card 412. In the example shown, the simulation engine 200 generates the production-environment rendering 484, based on the third card 432. The rendering 484 of the third card 432 can include rendering the video element 438.

According to examples, the simulation engine 200 generates and maintains a semantic structure of the collection 401 of cards. By maintaining a semantic structure, the simulation engine 200 can determine which design elements of the cards 402, 412, 432 are semantically the same with regards to the production-environment. For stateful design elements, the simulation engine 200 can record state information (e.g., reflecting playback time) in association with semantic identifiers of nodal elements of the semantic structure, representing design elements of the cards of the collection.

FIG. 4E illustrates a semantic structure that is determined for an example of FIG. 4A and FIG. 4B through FIG. 4D, in accordance with one or more embodiments. With reference to FIG. 4E, the simulation engine 200 determines the semantic structure in connection with the simulation engine 200 generating a production-environment rendering 480 of the first card. In examples such as shown, the semantic structure can include (in graph form): (i) a root node 440 (representing a card level design element); (ii) a page content node 442 connected as a child to the root node 440, the page content node 442 representing the page content design element 406; (iii) a video player node 444, connected as a child node to the page content node 442, representing the video player design element 404; (iv) a first suggestion box node 454, connected as a child node to the page content node 442, representing the suggestion box design element 416; (v) a second suggestion box node 464, connected as a child node to the page content node 442, representing the second suggestion box design element 426; (vi) a video element node 446, connected as a child node to the vide player node 444, representing first video design element 410; (vii) a second video player node 456, connected as a child node to the first suggestion box node 454, representing the second video player 418; (viii) a third video player node 466, connected as a child node to the second suggestion box node 464, representing the third video player 428; (ix) a second video element node 458, connected as a child node to the second video player node 456, representing the second video design element 420; and (x) (ix) a third video element node 468, connected as a child node to the third video player node 466, representing the third video design element 430.

The simulation engine 200 processes the third card 432 by determining the semantic structure the third card. Based on the semantic determination of the third card 432, the video element 438 of the third card 432 can be seen to have the same semantic identifier as the video element of the first card 402. Based at least in part on the design-mode nodal representation 209, the semantic identifier of each of the video element 410 and video element 438 can include:
“page content” node-->“video player” node-->“video element” 410.

Based on the semantic identifiers, the simulation engine 200 can determine the video elements 410, 438 to be the same, and state information recorded with the video element 410 after the initial rendering can be used to initiate rendering of the video element 438 when the rendering of the third card is generated.

With reference to an example as shown, the rendering of the video element 410 of the first card 402 is to be the same as the rendering of the video element 438 of the third card 432. However, in the design mode, the video element 410 and video element 438 are different design elements, having, for example, different nodal identifies with the design-mode nodal representation 209. Under conventional approaches, the video elements 410 and 438 can be rendered in the production-environment so as to appear the same, but the video elements may not be known to be the same. Accordingly, under conventional approaches, when the video element 438 is rendered in the simulation environment, the video element 438 may initiate from the beginning, rather than from the point where playback stopped after the rendering 480 is generated.

By contrast, under embodiments as described, the simulation engine 200 is able to recognize that the video elements 410 and 438 are semantically the same, meaning in the production-environment, the video element 410 of the first rendering 480 is the same as the video element 438 of the second third rendering 484. Accordingly, as described, the simulation engine 200 records state information reflecting, for example, the playback state of the video element 410 when the rendering 480 stops or terminates (e.g., when the rendering 482 is generated). When the rendering 484 is generated, the simulation engine 200 uses the recorded state information to initiate playback of the video element 438 from the playback time where playback was stopped or terminated with the first rendering 480. Among other technical benefits, the rendering of the sequence of cards results in a more accurate simulation of the production renderings.

Network Computer System

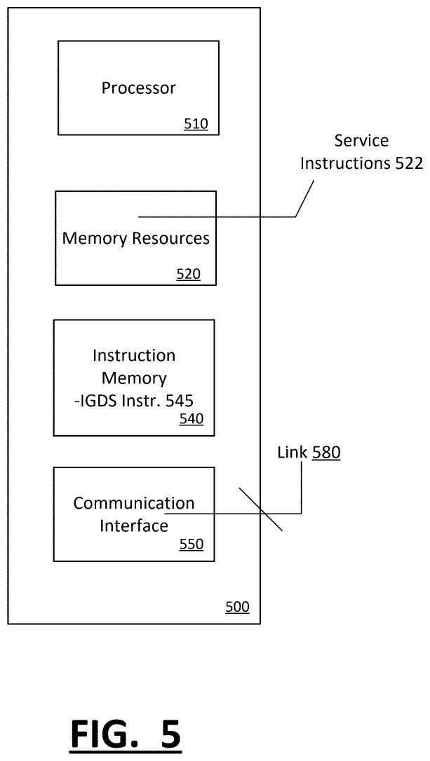

FIG. 5 illustrates a computer system on which one or more embodiments can be implemented. A computer system 500 can be implemented on, for example, a server or combination of servers. For example, the computer system 500 may be implemented as the network computing system 150 of FIG. 1A through FIG. 1C. Further, in some examples, the computer system 500 can provide instructions to the user device to enable the user device to implement functionality of the IGDS 100. Further, the computer system 500 can provide instructions to a user device, or otherwise perform operations to implement an example method (or steps therein) such as described with FIG. 3.

In one implementation, the computer system 500 includes processing resources 510, memory resources 520 (e.g., read-only memory (ROM) or random-access memory (RAM)), one or more instruction memory resources 540, and a communication interface 550. The computer system 500 includes at least one processor 510 for processing information stored with the memory resources 520, such as provided by a random-access memory (RAM) or other dynamic storage device, for storing information and instructions which are executable by the processor 510. The memory resources 520 may also be used to store temporary variables or other intermediate information during execution of instructions to be executed by the processor 510.

The communication interface 550 enables the computer system 500 to communicate with one or more user computing devices, over one or more networks (e.g., cellular network) through use of the network link 580 (wireless or a wire). Using the network link 580, the computer system 500 can communicate with one or more computing devices, specialized devices and modules, and/or one or more servers.

In examples, the processor 510 may execute service instructions 522, stored with the memory resources 520, in order to enable the network computing system to implement the network service 172 and operate as the network computing system 170 in examples such as described with FIG. 1A through FIG. 1C.

The computer system 500 may also include additional memory resources (“instruction memory 540”) for storing executable instruction sets (“IGDS instructions 545”) which are embedded with web-pages and other web resources, to enable user computing devices to implement functionality such as described with the IGDS 100.

As such, examples described herein are related to the use of the computer system 500 for implementing the techniques described herein. According to an aspect, techniques are performed by the computer system 500 in response to the processor 510 executing one or more sequences of one or more instructions contained in the memory 520. Such instructions may be read into the memory 520 from another machine-readable medium. Execution of the sequences of instructions contained in the memory 520 causes the processor 510 to perform the process steps described herein. In alternative implementations, hard-wired circuitry may be used in place of or in combination with software instructions to implement examples described herein. Thus, the examples described are not limited to any specific combination of hardware circuitry and software.

User Computing Device

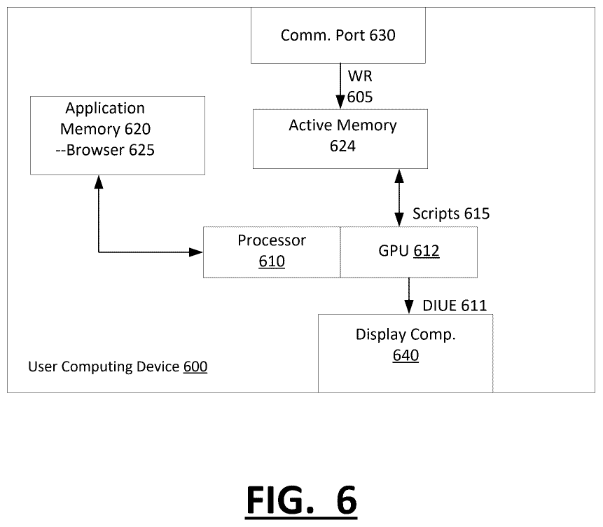

FIG. 6 illustrates a user computing device for use with one or more examples, as described. In examples, a user computing device 600 can correspond to, for example, a work station, a desktop computer, a laptop or other computer system having graphics processing capabilities that are suitable for enabling renderings of design interfaces and graphic design work. In variations, the user computing device 600 can correspond to a mobile computing device, such as a smartphone, tablet computer, laptop computer, VR or AR headset device, and the like.

In examples, the computing device 600 includes a central or main processor 610, a graphics processing unit 612, memory resources 620, and one or more communication ports 630. The computing device 600 can use the main processor 610 and the memory resources 620 to store and launch a browser 625 or other web-based application. A user can operate the browser 625 to access a network site of the network service 152, using the communication port 630, where one or more web pages or other resources 605 for the network service 152 (see FIG. 1A through FIG. 1C) can be downloaded. The web resources 605 can be stored in the active memory 624 (cache).

As described by various examples, the processor 610 can detect and execute scripts and other logic which are embedded in the web resource in order to implement the IGDS 100 (see FIG. 1A through FIG. 1C). Further, the processor 610 can execute scripts or instructions to perform an example method such as described with an example of FIG. 3. In some of the examples, some of the scripts 615 which are embedded with the web resources 605 can include GPU accelerated logic that is executed directly by the GPU 612. The main processor 610 and the GPU can combine to render a design interface under edit (“DUE 611”) on a display component 640. The rendered design interface can include web content from the browser 625, as well as design interface content and functional elements generated by scripts and other logic embedded with the web resource 605. By including scripts 615 that are directly executable on the GPU 612, the logic embedded with the web resource 615 can better execute the IGDS 100, as described with various examples.

### CONCLUSION

Although examples are described in detail herein with reference to the accompanying drawings, it is to be understood that the concepts are not limited to those precise examples. Accordingly, it is intended that the scope of the concepts be defined by the following claims and their equivalents. Furthermore, it is contemplated that a particular feature described either individually or as part of an example can be combined with other individually described features, or parts of other examples, even if the other features and examples make no mentioned of the particular feature. Thus, the absence of describing combinations should not preclude having rights to such combinations.

What is claimed is:

1. A computer system comprising:
one or more processors; and
a memory to store instructions;
wherein the one or more processes execute the instructions to perform operations comprising:
implementing a simulation environment in which a plurality of cards are individually renderable to simulate a user interface or presentation in production; and
processing each card of a sequence to determine a semantic structure for the sequence, the semantic structure including a plurality of nodes, each node of the plurality of nodes representing a production element of the simulated user interface or presentation in production;
wherein processing the sequence of multiple cards includes determining, based on the determined semantic structure, whether a design element of each of a first and a second card in the sequence represent a same production element of the user interface or presentation.

2. The computer system of claim 1, wherein the design element of each of the first card and the second card includes a stateful design element.

3. The computer system of claim 2, wherein the operations include:
rendering the first card in the sequence in the simulation environment;
determining state information for the stateful design element just prior to rendering the second card in the sequence in the simulation environment; and
recording the determined state information in association with a semantic identifier of the stateful design element.

4. The computer system of claim 3, further comprising:
a semantic memory component; and
wherein the one or more processors record the determined state information with the semantic memory component.

5. The computer system of claim 3, wherein the operations further comprise:
initiating rendering of the second card in the sequence in the simulation environment with the stateful design element having a state that is based on the determined state information.

6. The computer system of claim 5, wherein the stateful design element corresponds to a video element.

7. The computer system of claim 6, wherein the initiating rendering of the second card in the sequence includes initiating rendering of the video element with the state information.

8. The computer system of claim 7, wherein the state information includes a playback time when rendering of the first card stops, and wherein rendering of the video element with the state information includes initiating playback of the video element at a start time that is based on the playback time when rendering of the first card stopped.

9. The computing system of claim 2, wherein the operations include:
wherein determining, based on the determined semantic structure, whether a design element of each of the first and the second card in the sequence represent the same production element includes determining a semantic identifier for the design element of the first and second card, and determining whether the semantic identifiers are the same.

10. A computer-implemented method comprising:
implementing a simulation environment in which a plurality of cards are individually renderable to simulate a user interface or presentation in production; and
processing each card of a sequence to determine a semantic structure for the sequence, the semantic structure including a plurality of nodes, each node of the plurality of nodes representing a production element of the simulated user interface or presentation in production;
wherein processing the sequence of multiple cards includes determining, based on the determined semantic structure, whether a design element of each of a first and a second card in the sequence represent a same production element of the user interface or presentation.

11. The method of claim 10, wherein the design element of each of the first card and the second card includes a stateful design element.

12. The method of claim 11, further comprising:
rendering the first card in the sequence in the simulation environment;
determining state information for the stateful design element just prior to rendering the second card in the sequence in the simulation environment; and
recording the determined state information in association with a semantic identifier of the stateful design element.

13. The method of claim 12, further comprising:
initiating rendering of the second card in the sequence in the simulation environment with the stateful design element having a state that is based on the determined state information.

14. The method of claim 13, wherein the stateful design element corresponds to a video element.

15. The method of claim 14, wherein initiating rendering of the second card in the sequence includes initiating rendering of the video element with the state information.

16. The method of claim 15, wherein the state information includes a playback time when rendering of the first card stops, and wherein rendering of the video element with the state information includes initiating playback of the video element at a start time that is based on the playback time when rendering of the first card stopped.

17. A non-transitory computer-readable medium that stores instructions, which when executed by one or more processors of a computing system, cause the computer system to perform operations that include:
implementing a simulation environment in which a plurality of cards are individually renderable to simulate a user interface or presentation in production; and
processing each card of a sequence to determine a semantic structure for the sequence, the semantic structure including a plurality of nodes, each node of the plurality of nodes representing a production element of the simulated user interface or presentation in production;
wherein processing the sequence of multiple cards includes determining, based on the determined semantic structure, whether a design element of each of a first and a second card in the sequence represent a same production element of the user interface or presentation.

18. The non-transitory computer-readable medium of claim 17, wherein the design element of each of the first card and the second card includes a stateful design element.

19. The non-transitory computer-readable medium of claim 18, wherein the operations include:
rendering the first card in the sequence in the simulation environment;
determining state information for the stateful design element just prior to rendering the second card in the sequence in the simulation environment; and
recording the determined state information in association with a semantic identifier of the stateful design element.

20. The non-transitory computer-readable medium of claim 18, wherein the stateful design element corresponds to a video element.
